(19) United States
(12) Patent Application Publication
(10) Pub. No.: US 2006/0211215 A1
(43) Pub. Date: Sep. 21, 2006

(54) Semiconductor device and method of manufacturing the same

(75) Inventor: Hiroyasu Yoshida, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kanagawa (JP)

(21) Appl. No.: 11/373,910

(22) Filed: Mar. 14, 2006

(30) Foreign Application Priority Data
Mar. 15, 2005 (JP) 73308/2005

(51) Int. Cl. H01L 21/76

(52) U.S. Cl. 438/424

(57) ABSTRACT

Included are steps of: selectively etching a nitride film and a thermal oxide film in a thick gate insulating film forming region of a silicon substrate on which the thermal oxide film is formed with the nitride film formed on the thermal oxide film, and in which a trench with a predetermined depth is formed in an STI forming region; embedding a CVD oxide film in the trench and the thick gate insulating film forming region by the CVD method; and planarizing the CVD oxide film by the CMP method using, as a stopper, the nitride film in a region other than the STI forming region and the thick gate insulating film forming region.

### BACKGROUND OF THE INVENTION

1. Field of the Invention

The present invention relates to a semiconductor device having a dual gate insulating film in a shallow trench isolation (STI) structure and a method of manufacturing the same.

2. Description of Related Art

In a conventional method of manufacturing a semiconductor device having a dual gate insulating film in an STI structure, when the STI, a gate insulating film having a large thickness (thick gate insulating film), and a gate insulating film having a small thickness (thin gate insulating film) are formed, the thick and thin gate insulating films are formed after the STI is formed (see, for example, Japanese Patent Application Laid-open No. 2003-60025).

An example of a related method of manufacturing the semiconductor device having the dual gate insulating film in the STI structure includes the following steps of: first, forming a thermal oxide film 102 on a silicon substrate 101; forming a nitride film 103; after forming a photoresist (not shown), etching the nitride film 103 and the thermal oxide film 102 in a STI forming region 110 by using the photoresist as a mask; removing the photoresist; and forming trenches 101a with a predetermined depth by etching the silicon substrate 101 by using the nitride film 103 as a mask, (see, FIG. 5A). Next, a CVD (Chemical Vapor Deposition) oxide film 104 to be an STI is deposited on the substrate so that the CVD oxide film 104 is embedded in the trenches 101a of FIG. 5A (see, FIG. 5B). Next, the CVD oxide film 104 is planarized by the CMP (Chemical Mechanical Polishing) method using the nitride film 103 as a stopper (see, FIG. 5C). Next, the nitride film 103 of FIG. 5C is etched, and then the thermal oxide film 102 of FIG. 5C is etched (see, FIG. 5D). Next, a second thermal oxide film 105 to be a thick gate insulating film is formed (see, FIG. 5E). Next, a photoresist 107 is formed on a thick gate insulating film forming region 120 and the STI forming region 110 of the substrate, and the second thermal oxide film 105 of a thin gate insulating film forming region 130 is etched by using the photoresist 107 as a mask (see, FIG. 5F). Next, after removing the photoresist 107 of FIG. 5F, a third thermal oxide film 106 to be a thin gate insulating film, which is thinner than the thick gate insulating film (second thermal oxide film 105), is formed (see, FIG. 5G). Thus, the semiconductor device having the STI structure and dual gate insulating film can be obtained.

### SUMMARY OF THE INVENTION

However, in the conventional method of manufacturing the semiconductor device, a portion where the thick gate insulating film 105 is insufficiently thick in the vicinity of the boundary between the STI 104 and the thick gate insulating film 105 is made (see, FIG. 6A). This is because thermal oxidation rate varies depending on plane directions, and stress is concentrated in the boundary portion between the STI 104 and the thick gate insulating film 105 to cause the thick gate insulating film 105 to be thinner. Therefore, the concentration of electric field is locally occurred in the thick gate insulating film 105 to cause the withstand pressure of the thick gate insulating film 105 to be reduced.

In addition, due to the etching rate difference of the thermal oxide film and the CVD oxide film, a concave portion 104a which becomes lower than the surface of the thin gate insulating film 106 is formed on the STI 104 in the vicinity of the boundary between the thin gate insulating film 106 and the STI 104, thereby causing disadvantages in that residues of component (for example, polysilicon) of a gate (not shown) formed on the thin gate insulating film 106 remain on the concave portion 104a (see, FIG. 6B). Therefore, defective leakage is caused by the residues of the component of the gate.

In a first aspect of the present invention, in a method of manufacturing a semiconductor device having a dual gate insulating film in the STI structure, the method is characterized by including steps of: forming trenches in a periphery of a gate forming region of a semiconductor substrate; embedding insulators in the trenches and at the same time forming the insulators on the gate forming region; and forming a device isolation region in the trenches by removing the insulators and at the same time forming a gate insulating film on the gate forming region.

In a second aspect of the present invention, in the method of manufacturing the semiconductor device having the dual gate insulating film in the STI structure, the method is characterized by including steps of: selectively etching a nitride film and a first thermal oxide film in a thick gate insulating film forming region of a silicon substrate, on which the first thermal oxide film is formed with the nitride film formed on the first thermal oxide film, and in which trenches with a predetermined depth are formed in the STI forming region; embedding a second thermal oxide film in the trenches and the thick gate insulating film forming region by the CVD method; and planarizing the second thermal oxide film by the CMP method using, as stopper, the nitride film in a region other than the STI forming region and the thick gate insulating film forming region.

In a third aspect of the present invention, in the method of manufacturing the semiconductor device having the dual gate insulating film in the STI structure, the method is characterized by including steps of: forming a photoresist on a thin gate insulating film forming region of a silicon substrate on which a thermal oxide film is formed with a nitride film formed on the thermal oxide film, and in which trenches with a predetermined depth are formed in a STI forming region, and then selectively etching the nitride film of a thick gate insulating film forming region by using the photoresist as a mask; selectively etching the thermal oxide film of the thick gate insulating film forming region by using, as a mask, the nitride film of the thin gate insulating film forming region after removing the photoresist; embedding a CVD oxide film in the trenches and the thick gate insulating film forming region; and planarizing the CVD oxide film by the CMP method using, as a stopper, the nitride film of the thin gate insulating film forming region.

In a fourth aspect of the present invention, in the semiconductor device having the dual gate insulating film in the STI structure, the semiconductor device is characterized by including: a silicon substrate having trenches in the STI forming region; a CVD oxide film formed in the trenches and a thick gate insulating film forming region on the silicon substrate; and a thermal oxide film that is formed on the thin gate insulating film forming region on the silicon substrate and has a smaller thickness than the CVD oxide film has. The CVD oxide film has a shoulder at a higher position in the vicinity of the thermal oxide film than a surface of the thermal oxide film.

According to the present invention described in aspects 1 to 4, since the STI and the thick gate insulating film are formed of the same material and integrated, there is no boundary between the STI and the thick gate insulating film, thereby a thickness of the thick gate insulating film becomes uniformed. Therefore, the defective leakage is not caused by the concentration of electric field, and a quality thick gate insulating film can be formed.

According to the present invention, in the thin gate insulating film forming region, since thermal oxidation to form the thick gate insulating film is not carried out, it is difficult to generate a concave portion in the STI and occurrence of the residues of the gate component can be prevented.

### BRIEF DESCRIPTION OF THE DRAWINGS

FIGS. 1A to 1H are partial process sectional views showing schematically a method of manufacturing a semiconductor device according to a first embodiment of the present invention;

FIGS. 2A and 2B are enlarged schematic sectional views showing a configuration of the semiconductor device according to the first embodiment of the present invention, where 2A shows a thick gate insulating film forming region and 2B shows an STI forming region;

FIGS. 3A and 3B show schematic configurations before forming a gate of the semiconductor device according to the first embodiment of the present invention, where 3A is a plan view and 3B is a cross-sectional view;

FIGS. 4A and 4B show schematic configurations after forming the gate of the semiconductor device according to the first embodiment of the present invention, where 4A is a plan view and 4B is a cross-sectional view;

FIGS. 5A to 5G are partial process sectional views showing schematically a method of manufacturing a semiconductor device according to a related art;

FIGS. 6A and 6B are enlarged schematic sectional views showing a configuration of the semiconductor device according to the conventional example, where 6A shows a thick gate insulating film forming region and 6B shows a thin gate insulating film forming region.

### DETAILED DESCRIPTION OF THE PREFERRED EMBODIMENT

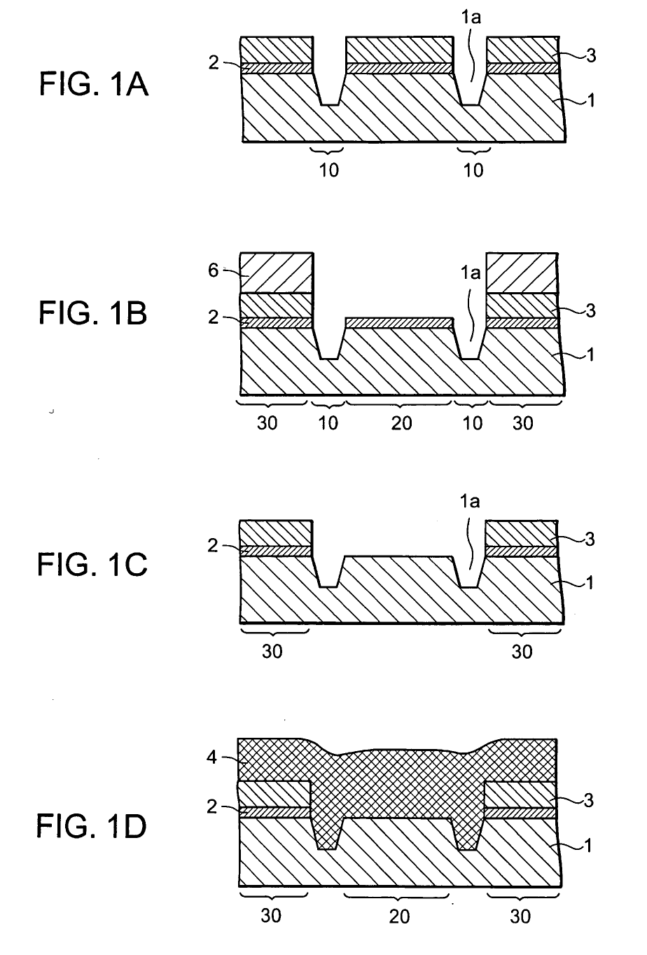

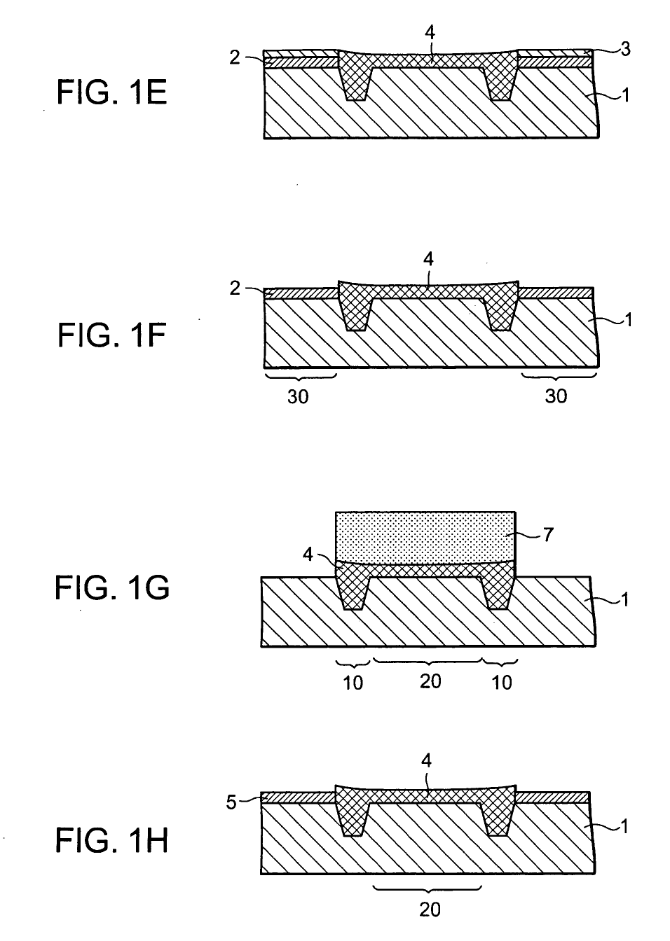

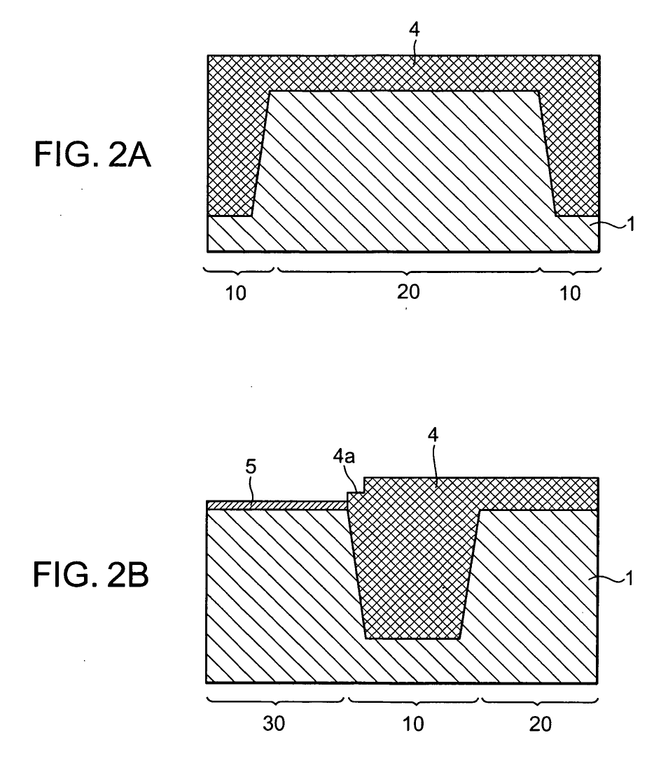

A method of manufacturing a semiconductor device according to a first embodiment of the present invention will be described by referring to the accompanying drawings. FIGS. 1A to 1H are partial process sectional views showing schematically the method of manufacturing the semiconductor device according to the first embodiment of the present invention. FIGS. 2A and 2B are enlarged schematic sectional views showing a configuration of the semiconductor device according to the first embodiment of the present invention, where 2A shows a thick gate insulating film forming region and 2B shows an STI forming region. It should be noted that the semiconductor device shown in FIGS. 1A to 2B is not a finished product but a work-in-progress product.

The method of the semiconductor device includes the following steps of: first, forming a thermal oxide film 2 on a silicon substrate 1 (semiconductor substrate); forming a nitride film 3; after forming a photoresist (not shown), etching the nitride film 3 and the thermal oxide film 2 in the STI forming region (device isolation region) 10 by using the photoresist as a mask; removing the photoresist; and forming trenches 1a with a predetermined depth by etching the silicon substrate 1 by using the nitride film 3 as a mask (see, FIG. 1A).

Next, a photoresist 6 is formed on a region (thin gate insulating film forming region 30) other than a thick gate insulating film forming region 20 and the STI forming region 10, and the nitride film 3 is selectively etched by using the photoresist 6 as a mask (see, FIG. 1B). It should be noted that at this stage, the nitride film 3 of the thin gate insulating film forming region 30 remains.

Next, after removing the photoresist 6 of FIG. 1B, the thermal oxide film 2 is selectively etched by using, as a mask, the nitride film 3 of the thin gate insulating film forming region 30 (see, FIG. 1C).

Next, a CVD oxide film 4 to be an STI and a thick gate insulating film (insulator) is deposited on the substrate, and is embedded in the trenches 1a of FIG. 1C and the thick gate insulating film forming region 20 (see, FIG. 1D). Here, as for the CVD oxide film 4, for example, a high density plasma (HDP) CVD oxide film and a high temperature oxide (HTO) CVD film can be used.

Next, the CVD oxide film 4 is planarized by the CMP method using the nitride film 3 as a stopper (see, FIG. 1E).

Next, the nitride film 3 of FIG. 1E is selectively etched (see, FIG. 1F).

Next, a photoresist 7 is formed on the CVD oxide film 4 (the thick gate insulating film forming region 20 and the STI forming region 10), and the thermal oxide film 2 of FIG. 1E is etched by using the photoresist 7 as a mask (see, FIG. 1G).

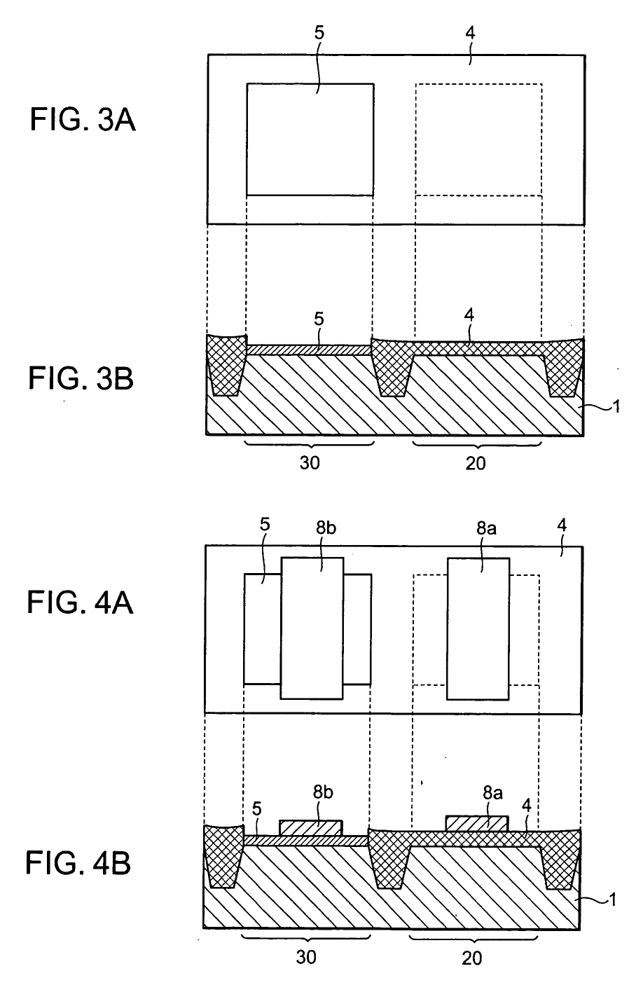

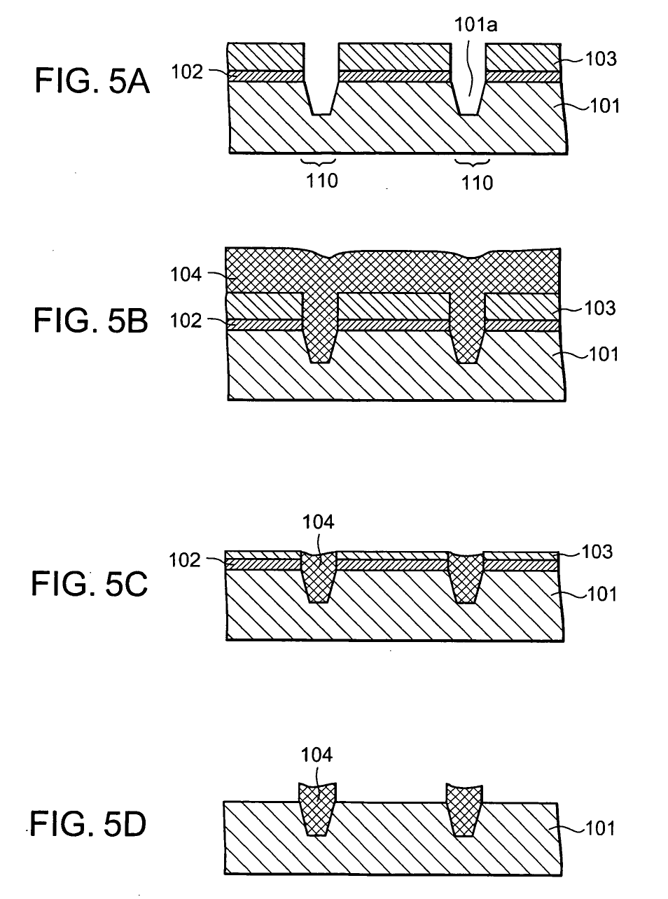

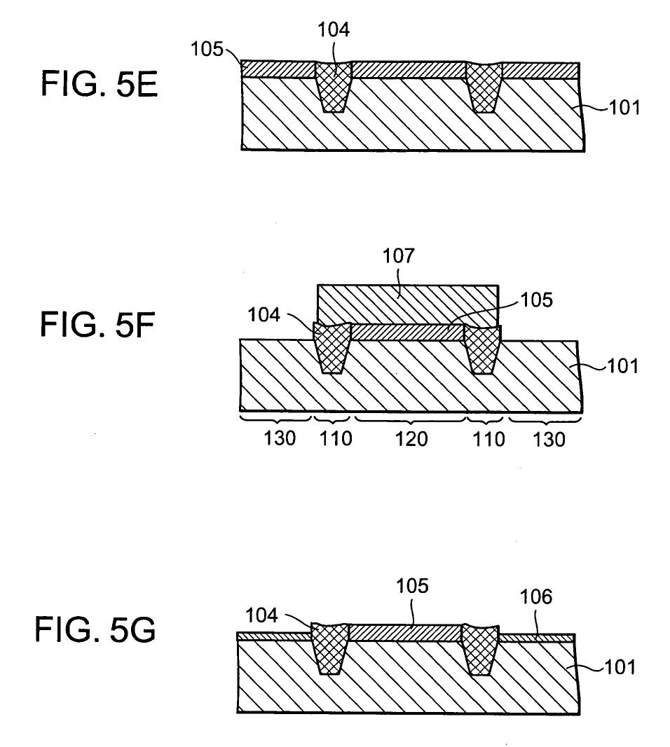

Next, after removing the photoresist 7 of FIG. 1G, a second thermal oxide film 5 to be a thin gate insulating film is formed (see, FIG. 1H). Here, a thickness of the second thermal oxide film 5 is set to be smaller than that of the CVD oxide film 4 of the thick gate insulating film forming region 20. With this, a semiconductor device having the STI structure and dual gate insulating film can be obtained (see, FIGS. 3A and 3B). After that, without patterning the CVD oxide film 4 of the thick gate insulating film forming region 20, gates 8a and 8b formed of polysilicon are formed in a gate forming region on (the CVD oxide film 4 of) the thick gate insulating film forming region 20 and (the second thermal oxide film 5 of) the thin gate insulating film forming region 30 (see, FIGS. 4A and 4B).

According to the first embodiment, if the STI and the thick gate insulating film are formed at the same time by the CVD oxide film 4 at the time of forming the STI (see, FIGS. 1D and 1E), as shown in FIG. 2A, deterioration of the shape of the thick gate insulating film (the vicinity of the boundary with the STI becomes thin) is not caused since the STI and the thick gate insulating film are formed of the same material of the CVD oxide film 4 and integrated so that the boundary between the STI and the thick gate insulating film is not present. In other words, the thickness of the CVD oxide film 4 of the thick gate insulating film forming region 20 becomes uniform, and the defective leakage caused by the concentration of electric field does not occur, therefore a quality thick gate insulating film can be formed.

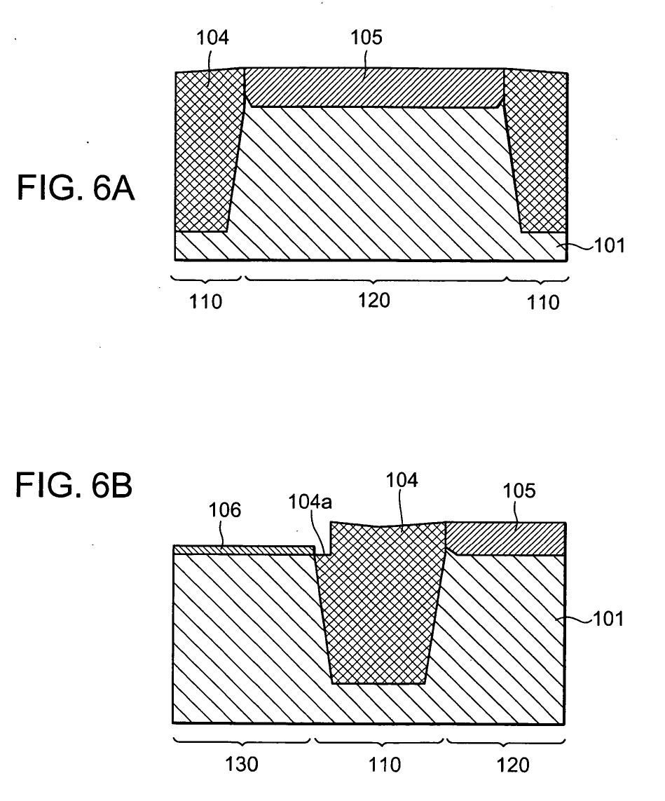

In addition, in the thin gate insulating film forming region 30, since only the thermal oxide film 2 is etched before the thin gate insulating film 5 is formed (see, FIG. 1F) (that is, thermal oxidation to form a thick gate insulating film is not carried out), the amount of etching the thermal oxide film is smaller compared with that of the conventional technology. Therefore, it is difficult to occur a dent, that is, a concave portion 104a of FIG. 6B on the CVD oxide film 4 as shown in FIG. 1B (that is, only a shoulder 4a is formed at a higher position than a surface of the thin gate insulating film 5 on the STI 4), and the occurrence of the residues of the gate component can be prevented.

Although the invention has been described with reference to specific embodiments, this description is not meant to be construed in a limiting sense. Various modifications of the disclosed embodiments will become apparent to persons skilled in the art upon reference to the description of the invention. It is therefore contemplated that the appended claims will cover any modifications or embodiments as fall within the true scope of the invention.

What is claimed is:

1. A method of manufacturing a semiconductor device, comprising:
forming a trench in a periphery of a gate forming region of a semiconductor substrate;
embedding an insulator in the trench and, at the same time, forming the insulator on the gate forming region;
forming a device isolation region in the trench by removing the insulator and, and
forming a gate insulating film on the gate forming region.

2. A method of manufacturing a semiconductor device, comprising:
selectively etching a nitride film and a first thermal oxide film in a fist gate insulating film forming region of a semiconductor substrate on which the first thermal oxide film is formed with the nitride film formed on the first thermal oxide film, in order to form a trench in an STI forming region;
forming a second thermal oxide film in said trench and said first gate insulating film forming region by a chemical vapor deposition (CVD) method; and
planarizing the second thermal oxide film by the chemical and mechanical polishing (CMP) method using, as a stopper, the nitride film in a region other than the STI forming region and the first gate insulating film forming region.

3. The method according to claim 2, further comprising:
selectively etching the nitride film and the first thermal oxide film in a region other than the STI forming region and the first gate insulating film forming region; and
forming a third oxide film that is formed in a region other than the STI forming region and the first gate insulating film forming region and has a smaller thickness than the second oxide film.

4. A method of manufacturing a semiconductor device, comprising:
forming a photoresist on a first gate insulating film forming region of a semiconductor substrate on which a nitride film is formed on a thermal oxide film, and in which a trench is formed in an STI forming region;
etching the nitride film of a first gate insulating film forming region by using the photoresist as a mask;
after removing the photoresist, etching the thermal oxide film of the first gate insulating film forming region by using, as a mask;
forming a CVD oxide film in the trench and the first gate insulating film forming region; and
planarizing the CVD oxide film by the CMP method using, as a stopper, the nitride film of a second gate insulating film forming region.

5. The method according to claim 4, further comprising:
selectively etching the nitride film of the second gate insulating film forming region;
forming a second photoresist on the first gate insulating film forming region and the STI forming region of the CVD oxide film;
etching the thermal oxide film of the second gate insulating film forming region by using the second photoresist as a mask;
after removing the second photoresist, in the second gate insulating film forming region, and
forming a second thermal oxide film having a smaller thickness than the CVD oxide film of the thick gate insulating film forming region has.
